(19) United States
(12) Patent Application Publication
(10) Pub. No.: US 2024/0195153 A1
(43) Pub. Date: Jun. 13, 2024

(54) EMITTER ASSEMBLY WITH VERTICAL CAVITY SURFACE EMITTING LASER (VCSEL) CLUSTERS

(71) Applicant: Lumentum Operations LLC, San Jose, CA (US)

(72) Inventors: Wei SHI, San Jose, CA (US); Joseph LEIGH, Santa Clara, CA (US); Suhit Ranjan DAS, San Jose, CA (US); Huanlin ZHU, San Jose, CA (US); Raman SRINIVASAN, Fremont, CA (US); Gianluca BACCHIN, Albuquerque, NM (US); Yuefa LI, San Jose, CA (US); Jacob U. LOPEZ RUVALCABA, Albuquerque, NM (US); Lijun ZHU, Dublin, CA (US); Qianhuan YU, Sunnyvale, CA (US)

(21) Appl. No.: 18/194,156

(22) Filed: Mar. 31, 2023

Related U.S. Application Data
(60) Provisional application No. 63/386,527, filed on Dec. 8, 2022.

(51) Int. Cl. H01S 5/42; H01S 5/0234; H01S 5/0237; H01S 5/024; H01S 5/183

(52) U.S. Cl. CPC H01S 5/423; H01S 5/0234; H01S 5/0237; H01S 5/02469; H01S 5/18305

(57) ABSTRACT

In some implementations, an emitter assembly includes a vertical cavity surface emitting laser (VCSEL) chip including a plurality of VCSELs in a bottom-emitting configuration, and multiple VCSELs, of the plurality of VCSELs, may be grouped in a cluster. The emitter assembly may include a carrier, and the VCSEL chip may be in a flip chip configuration with the carrier. The emitter assembly may include a conductive pillar electrically connected to the multiple VCSELs grouped in the cluster.

### CROSS-REFERENCE TO RELATED APPLICATION

This Patent application claims priority to U.S. Provisional Patent Application No. 63/386,527, filed on Dec. 8, 2022, and entitled “MASS REFLOW OF A VERTICAL CAVITY SURFACE EMITTING LASER ON AN INTEGRATED CIRCUIT CHIP.” The disclosure of the prior Application is considered part of and is incorporated by reference into this Patent Application.

### TECHNICAL FIELD

The present disclosure relates generally to vertical cavity surface emitting lasers (VCSELs) and to an emitter assembly with VCSEL clusters.

### BACKGROUND

A vertical-emitting laser device, such as a VCSEL, is a laser in which a beam is emitted in a direction perpendicular to a surface of a substrate (e.g., vertically from a surface of a semiconductor wafer). Multiple vertical-emitting devices may be arranged in an array with a common substrate.

### SUMMARY

In some implementations, an emitter assembly includes a VCSEL chip including a plurality of VCSELs in a bottom-emitting configuration, and multiple VCSELs, of the plurality of VCSELs, may be grouped in a cluster. The emitter assembly may include a carrier, and the VCSEL chip may be in a flip chip configuration with the carrier. The emitter assembly may include a conductive pillar electrically connected to the multiple VCSELs grouped in the cluster.

In some implementations, a VCSEL chip includes a plurality of VCSELs in a bottom-emitting configuration, and multiple VCSELs, of the plurality of VCSELs, may be grouped in a cluster. The VCSEL chip may include an electrical contact shared by the multiple VCSELs grouped in the cluster. The electrical contact may be electrically connected to the multiple VCSELs, and the electrical contact may be configured to electrically connect to a conductive pillar that provides electrical connection of the VCSEL chip and a carrier.

In some implementations, a method includes assembling a VCSEL chip in a flip chip configuration with a carrier to produce an emitter assembly. The VCSEL chip may include a plurality of VCSELs, and multiple VCSELs, of the plurality of VCSELs, may be grouped in a cluster that shares an electrical contact. A conductive pillar may electrically connect to the electrical contact of the cluster of the multiple VCSELs. The method may include performing a solder reflow procedure on the emitter assembly.

### BRIEF DESCRIPTION OF THE DRAWINGS

FIGS. 1A and 1B are diagrams illustrating a top-view of an example emitter and a cross-sectional view of the example emitter along line X-X, respectively.

FIG. 2 shows a sectional view of an example emitter assembly.

FIG. 3 shows a top view of an example VCSEL chip.

FIG. 4 shows a top view of an alternative configuration of an example VCSEL chip.

FIG. 5 shows a top view of an alternative configuration of an example VCSEL chip.

FIG. 6 shows a sectional view of an example emitter assembly.

FIG. 7 shows a top view of an example VCSEL chip.

FIG. 8 is a flowchart of an example process associated with manufacturing an emitter assembly with VCSEL clusters.

### DETAILED DESCRIPTION

The following detailed description of example implementations refers to the accompanying drawings. The same reference numbers in different drawings may identify the same or similar elements.

In some examples, a top-emitting vertical cavity surface emitting laser (VCSEL) chip may be mounted on a substrate side-by-side with an integrated circuit (IC) driver chip for the VCSEL chip and connected by wire bonding and substrate traces. In some other examples, a bottom-emitting VCSEL chip may be flip chip bonded on an IC driver chip (which may be referred to as a VCSEL-on-driver (VoD) configuration), thereby shortening connections between the VCSEL chip and the IC driver chip and improving control over the VCSEL chip. A time-of-flight (ToF) camera may include such a VoD device to achieve improved three-dimensional (3D) sensing accuracy.

In a VoD device, an emitter pitch of a VCSEL chip may be in a range from approximately 35 micrometers (μm) to 50 μm depending on particular optical requirements for the VoD device. However, a pitch of electrical contacts (e.g., solder bumps or bond pads) of an IC driver chip of the VOD device may be 45 μm or greater (e.g., 60 μm). In other words, the VCSEL chip may have a finer pitch than the IC driver chip. In some cases, to resolve the mismatch in pitches, the pitch of the electrical contacts of the IC driver chip may be redistributed to match the pitch of the VCSEL chip by wafer reconstruction of the IC driver chip using a redistribution layer (RDL). In other words, the redistribution layer may provide reduction of the pitch of the electrical contacts of the IC driver chip. In some examples, conductive (e.g., copper (Cu)) pillars may be used for connecting the VCSEL chip to the IC driver chip.

When these conductive pillars have a fine pitch, achieving passive alignment using solder reflow in mass production is difficult because vibration in a transfer belt or a reflow oven belt may misalign the VCSEL chip before the solder is melted. Thus, for smaller pitches (e.g., 45 μm or less), bonding of the VCSEL chip to the IC chip may be achieved using thermal compression bonding (TCB) with active alignment rather than conventional solder mass reflow. Compared to solder mass reflow, TCB is complex, expensive, and associated with a low throughput, such as a low units per hour (UPH). For example, TCB may involve a temperature ramp-up and cooling down of a bonding head, which can be slow, resulting in low throughput. In some examples, chip-on-wafer TCB bonding of VCSEL chips to an IC wafer may be used to improve throughput. However, chip-on-wafer TCB bonding may be unsuitable for various solders (e.g., tin/silver solders) because the bonding temperature may remelt the solder of neighboring chips.

Some implementations described herein enable the use of solder mass reflow for an emitter assembly having an array of VCSELs arranged with a fine pitch. In some implementations, the emitter assembly may include a carrier (e.g., an IC chip, a circuit board, or the like) and a VCSEL chip in a flip chip configuration with the carrier. VCSELs of the VCSEL chip may be grouped into clusters, and the VCSELs of a cluster may share a common electrical contact. The emitter assembly may include conductive pillars electrically connected to respective electrical contacts of the clusters to thereby electrically connect the VCSEL chip and the carrier. Because the conductive pillars are electrically connected to clusters of VCSELs, rather than individual VCSELs, the conductive pillars may be larger and may be arranged with a greater pitch that is suitable for solder mass reflow. Accordingly, the emitter assembly may be manufactured with a reduced cost and complexity and at a greater throughput using solder mass reflow.

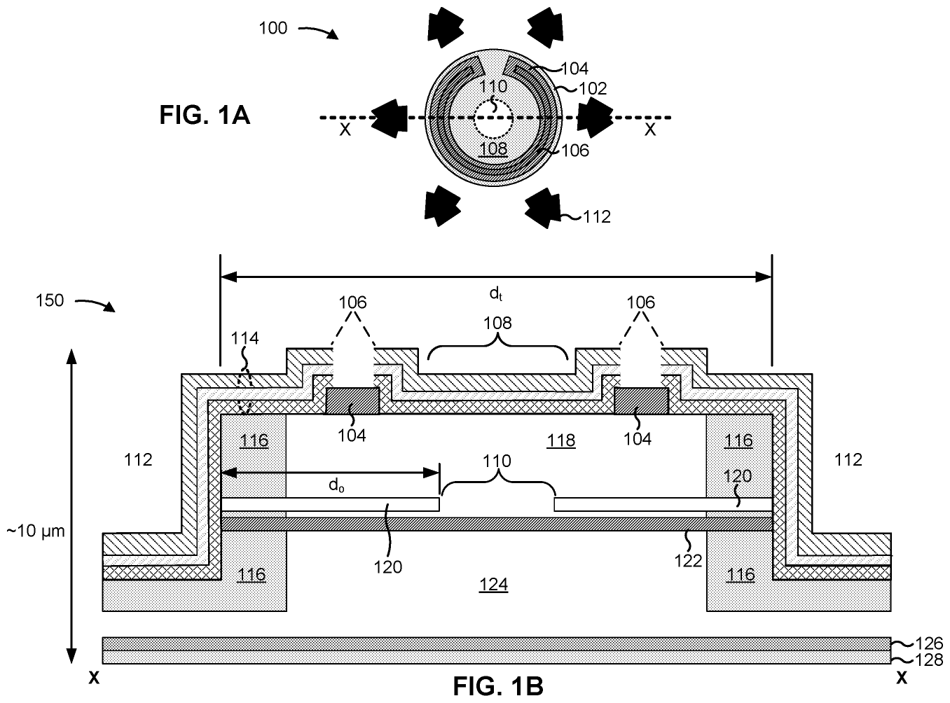

FIGS. 1A and 1B are diagrams illustrating a top-view of an example emitter 100 and a cross-sectional view 150 of the example emitter 100 along line X-X, respectively. As shown in FIG. 1A, emitter 100 may include a set of emitter layers constructed in an emitter architecture. In some implementations, emitter 100 may correspond to one or more vertical-emitting devices described herein.

As shown in FIG. 1A, emitter 100 may include an implant protection layer 102 that is circular in shape in this example. In some implementations, implant protection layer 102 may have another shape, such as an elliptical shape, a polygonal shape, or the like. Implant protection layer 102 is defined based on a space between sections of implant material (not shown) included in emitter 100.

As shown by the medium gray and dark gray areas in FIG. 1A, emitter 100 includes an ohmic metal layer 104 (e.g., a P-Ohmic metal layer or an N-Ohmic metal layer) that is constructed in a partial ring-shape (e.g., with an inner radius and an outer radius). The medium gray area shows an area of ohmic metal layer 104 covered by a protective layer (e.g., a dielectric layer or a passivation layer) of emitter 100, and the dark gray area shows an area of ohmic metal layer 104 exposed by via 106, described below. As shown, ohmic metal layer 104 overlaps with implant protection layer 102. Such a configuration may be used, for example, in the case of a P-up/top-emitting emitter 100. In the case of a bottom-emitting emitter 100, the configuration may be adjusted as needed.

Not shown in FIG. 1A, emitter 100 includes a protective layer in which via 106 is formed (e.g., etched). The dark gray area shows an area of ohmic metal layer 104 that is exposed by via 106 (e.g., the shape of the dark gray area may be a result of the shape of via 106) while the medium gray area shows an area of ohmic metal layer 104 that is covered by some protective layer. The protective layer may cover all of the emitter other than the vias. As shown, via 106 is formed in a partial ring-shape (e.g., similar to ohmic metal layer 104) and is formed over ohmic metal layer 104 such that metallization on the protection layer contacts ohmic metal layer 104. In some implementations, via 106 and/or ohmic metal layer 104 may be formed in another shape, such as a full ring-shape or a split ring-shape.

As further shown, emitter 100 includes an optical aperture 108 in a portion of emitter 100 within the inner radius of the partial ring-shape of ohmic metal layer 104. Emitter 100 emits a laser beam via optical aperture 108. As further shown, emitter 100 also includes a current confinement aperture 110 (e.g., an oxide aperture formed by an oxidation layer of emitter 100 (not shown)). Current confinement aperture 110 is formed below optical aperture 108.

As further shown in FIG. 1A, emitter 100 includes a set of trenches 112 (e.g., oxidation trenches) that are spaced (e.g., equally, unequally) around a circumference of implant protection layer 102. How closely trenches 112 can be positioned relative to the optical aperture 108 is dependent on the application, and is typically limited by implant protection layer 102, ohmic metal layer 104, via 106, and manufacturing tolerances.

The number and arrangement of layers shown in FIG. 1A are provided as an example. In practice, emitter 100 may include additional layers, fewer layers, different layers, or differently arranged layers than those shown in FIG. 1A. For example, while emitter 100 includes a set of six trenches 112, in practice, other configurations may be used, such as a compact emitter that includes five trenches 112, seven trenches 112, or another quantity of trenches. In some implementations, trenches 112 may encircle emitter 100 to form a mesa structure dₜ (shown in FIG. 1B). As another example, while emitter 100 is a circular emitter design, in practice, other designs may be used, such as a rectangular emitter, a hexagonal emitter, an elliptical emitter, or the like. Additionally, or alternatively, a set of layers (e.g., one or more layers) of emitter 100 may perform one or more functions described as being performed by another set of layers of emitter 100, respectively.

Notably, while the design of emitter 100 is described as including a VCSEL, other implementations are contemplated. For example, the design of emitter 100 may apply in the context of another type of optical device, such as a light emitting diode (LED), or another type of vertical emitting (e.g., top emitting or bottom emitting) optical device. Additionally, the design of emitter 100 may apply to emitters of any wavelength, power level, and/or emission profile. In other words, emitter 100 is not particular to an emitter with a given performance characteristic.

As shown in FIG. 1B, the example cross-sectional view may represent a cross-section of emitter 100 that passes through, or between, a pair of trenches 112 (e.g., as shown by the line labeled “X-X” in FIG. 1A). As shown, emitter 100 may include a backside cathode layer 128, a substrate layer 126, a bottom mirror 124, an active region 122, an oxidation layer 120, a top mirror 118, an implant isolation material 116, a protective layer 114 (e.g., a dielectric passivation/mirror layer), and an ohmic metal layer 104. As shown, emitter 100 may have, for example, a total height that is approximately 10 micrometers (μm).

Backside cathode layer 128 may include a layer that makes electrical contact with substrate layer 126. For example, backside cathode layer 128 may include an annealed metallization layer, such as an AuGeNi layer, a PdGeAu layer, or the like.

Substrate layer 126 may include a base substrate layer upon which epitaxial layers are grown. For example, substrate layer 126 may include a semiconductor layer, such as a GaAs layer, an InP layer, and/or another type of semiconductor layer.

Bottom mirror 124 may include a bottom reflector layer of emitter 100. For example, bottom mirror 124 may include a distributed Bragg reflector (DBR).

Active region 122 may include a layer that confines electrons and defines an emission wavelength of emitter 100. For example, active region 122 may be a quantum well.

Oxidation layer 120 may include an oxide layer that provides optical and electrical confinement of emitter 100. In some implementations, oxidation layer 120 may be formed as a result of wet oxidation of an epitaxial layer. For example, oxidation layer 120 may be an Al₂O₃ layer formed as a result of oxidation of an AlAs or AlGaAs layer. Trenches 112 may include openings that allow oxygen (e.g., dry oxygen, wet oxygen) to access the epitaxial layer from which oxidation layer 120 is formed.

Current confinement aperture 110 may include an optically active aperture defined by oxidation layer 120. A size of current confinement aperture 110 may range, for example, from approximately 4 μm to approximately 20 μm. In some implementations, a size of current confinement aperture 110 may depend on a distance between trenches 112 that surround emitter 100. For example, trenches 112 may be etched to expose the epitaxial layer from which oxidation layer 120 is formed. Here, before protective layer 114 is formed (e.g., deposited), oxidation of the epitaxial layer may occur for a particular distance (e.g., identified as do in FIG. 1B) toward a center of emitter 100, thereby forming oxidation layer 120 and current confinement aperture 110. In some implementations, current confinement aperture 110 may include an oxide aperture. Additionally, or alternatively, current confinement aperture 110 may include an aperture associated with another type of current confinement technique, such as an etched mesa, a region without ion implantation, lithographically defined intra-cavity mesa and regrowth, or the like.

Top mirror 118 may include a top reflector layer of emitter 100. For example, top mirror 118 may include a DBR.

Implant isolation material 116 may include a material that provides electrical isolation. For example, implant isolation material 116 may include an ion implanted material, such as a hydrogen/proton implanted material or a similar implanted element to reduce conductivity. In some implementations, implant isolation material 116 may define implant protection layer 102.

Protective layer 114 may include a layer that acts as a protective passivation layer, and which may act as an additional DBR. For example, protective layer 114 may include one or more sub-layers (e.g., a dielectric passivation layer and/or a mirror layer, a SiO₂ layer, a Si₃N₄ layer, an Al₂O₃ layer, or other layers) deposited (e.g., by chemical vapor deposition, atomic layer deposition, or other techniques) on one or more other layers of emitter 100.

As shown, protective layer 114 may include one or more vias 106 that provide electrical access to ohmic metal layer 104. For example, via 106 may be formed as an etched portion of protective layer 114 or a lifted-off section of protective layer 114. Optical aperture 108 may include a portion of protective layer 114 over current confinement aperture 110 through which light may be emitted.

Ohmic metal layer 104 may include a layer that makes electrical contact through which electrical current may flow. For example, ohmic metal layer 104 may include a Ti and Au layer, a Ti and Pt layer and/or an Au layer, or the like, through which electrical current may flow (e.g., through a bondpad (not shown) that contacts ohmic metal layer 104 through via 106). Ohmic metal layer 104 may be P-ohmic, N-ohmic, or other forms known in the art. Selection of a particular type of ohmic metal layer 104 may depend on the architecture of the emitters and is well within the knowledge of a person skilled in the art. Ohmic metal layer 104 may provide ohmic contact between a metal and a semiconductor, may provide a non-rectifying electrical junction, and/or may provide a low-resistance contact. In some implementations, emitter 100 may be manufactured using a series of steps. For example, bottom mirror 124, active region 122, oxidation layer 120, and top mirror 118 may be epitaxially grown on substrate layer 126, after which ohmic metal layer 104 may be deposited on top mirror 118. Next, trenches 112 may be etched to expose oxidation layer 120 for oxidation. Implant isolation material 116 may be created via ion implantation, after which protective layer 114 may be deposited. Via 106 may be etched in protective layer 114 (e.g., to expose ohmic metal layer 104 for contact). Plating, seeding, and etching may be performed, after which substrate layer 126 may be thinned and/or lapped to a target thickness. Finally, backside cathode layer 128 may be deposited on a bottom side of substrate layer 126.

The number, arrangement, thicknesses, order, symmetry, or the like, of layers shown in FIG. 1B are provided as an example. In practice, emitter 100 may include additional layers, fewer layers, different layers, differently constructed layers, or differently arranged layers than those shown in FIG. 1B. Additionally, or alternatively, a set of layers (e.g., one or more layers) of emitter 100 may perform one or more functions described as being performed by another set of layers of emitter 100, and any layer may comprise more than one layer.

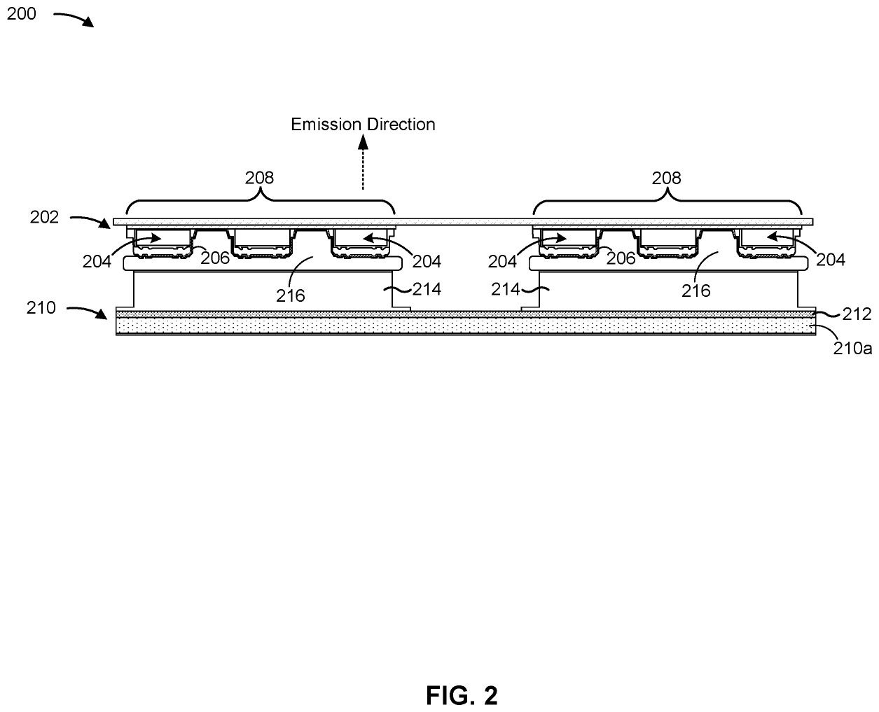

FIG. 2 shows a sectional view of an example emitter assembly 200. The emitter assembly 200 may include a VCSEL chip 202 (e.g., a VCSEL device). The VCSEL chip 202 may include a plurality of VCSELs 204 (i.e., a VCSEL array). For example, the VCSEL chip 202 may include a semiconductor die with the VCSELs 204 formed therein. In some implementations, the VCSELs 204 may be arranged, evenly-spaced or unevenly-spaced, in a plurality of rows, and alternating rows may be shifted relative to each other. A first spacing (e.g., a minimum spacing) of the VCSELs 204 from each other (from centers of the VCSELs 204) may define a first pitch (e.g., a first minimum pitch) associated with the VCSEL chip 202. The VCSELs 204 may be configured in a similar manner as described in connection with FIGS. 1A-1B. In some implementations, the VCSELs 204 may be in a bottom-emitting configuration. For example, in a bottom-emitting configuration, a top of a VCSEL 204 may be covered by an electrical contact (e.g., a bond pad), and the VCSEL 204 may emit light down through a substrate of the VCSEL 204.

The emitter assembly 200 may include a plurality of first electrical contacts 206 (e.g., bond pads). As shown, multiple VCSELs 204 may be grouped in a cluster 208. The cluster 208 of VCSELs 204 may share an electrical contact 206 (i.e., a common electrical contact 206). For example, the electrical contact 206 may extend, uninterrupted, on the multiple VCSELs 204. In some implementations, the multiple VCSELs 204 of the cluster 208 may be associated with respective electrical contacts 206 that are electrically connected with each other via a solder cap, as described herein. Thus, control of the VCSELs 204 (e.g., turning on or turning off of the VCSELs 204) may be per cluster 208.

The emitter assembly 200 may include a carrier 210 for the VCSEL chip 202. The carrier 210 may include a base layer 210a, such as an IC chip (e.g., a driver chip for the VCSEL chip 202), a substrate (e.g., a circuit board, such as a printed circuit board), or the like. For example, the emitter assembly 200 may include a VOD device. The carrier 210 may include a plurality of second electrical contacts (e.g., bond pads), not shown in FIG. 2. A second spacing of the second electrical contacts from each other (from centers of the second electrical contacts) may define a second pitch associated with the carrier 210. In some implementations, the second pitch may be different from the first pitch. For example, the second pitch may be greater than the first pitch. In some implementations, the first pitch may be less than 45 μm (e.g., 40 μm), which may be referred to as a “fine pitch,” and the second pitch may be greater than or equal to 45 μm (e.g., 60 μm). In some implementations, the first pitch and the second pitch may be the same.

In some implementations, the carrier 210 may include a surface layer 212 disposed on the base layer 210a. The surface layer 212 may include an isolation layer, a protective layer, or a redistribution layer. The surface layer 212 may include a polymer, such as polyimide, or SiO₂. As a redistribution layer, the surface layer 212 may include a dielectric material (e.g., polyimide). In some implementations, as a redistribution layer, the surface layer 212 may include (e.g., in the polyimide) a plurality of conductive traces (not shown), respectively connected to the second electrical contacts, configured to redistribute the second electrical contacts of the carrier 210 to different locations. For example, the redistribution layer may redistribute one or more second electrical contacts associated with a cluster 208 to be in alignment with the cluster 208.

In some implementations, the VCSEL chip 202 may be in a flip chip configuration (i.e., a direct chip attach configuration) with the carrier 210. That is, the VCSEL chip 202 may be disposed on the carrier 210. The emitter assembly 200 may include a plurality of conductive pillars 214 (e.g., posts, columns, or the like) that connect the VCSEL chip 202 and the carrier 210. The conductive pillars 214 may include a metal, such as copper, silver, gold, or the like. A conductive pillar 214 may include a solder cap 216 (e.g., composed of a tin/silver solder) at an end of the conductive pillar 214 (e.g., with a nickel layer between the conductive pillar 214 and the solder cap 216).

A single conductive pillar 214 may be electrically connected to an electrical contact 206 for a cluster 208. A solider cap 216 of the conductive pillar 214 may be electrically connected to the multiple VCSELs 204 of the cluster 208. For example, the solder cap 216 of the conductive pillar 214 may surround the multiple VCSELs 204 of the cluster 208 (e.g., such that the solder cap 216 electrically connects to the multiple VCSELs 204 even if the multiple VCSELs have separate electrical contacts). Thus, the conductive pillars 214 may electrically connect the first electrical contacts 206 associated with the clusters 208 and the second electrical contacts.

For example, first ends of the conductive pillars 214 may be electrically and mechanically connected to the first electrical contacts 206, and second ends of the conductive pillars 214 may be electrically and mechanically connected to the conductive traces of the surface layer 212 (and electrically connected to the second electrical contacts via the conductive traces). As an example, the surface layer 212 may be disposed on the base layer 210a of the carrier 210 between the base layer 210a and the conductive pillars 214, and the surface layer 212 may electrically connect the second electrical contacts and the conductive pillars 214. In some implementations, the conductive pillars 214 may extend from the VCSEL chip 202 to the carrier 210 (e.g., the solder caps 216 may be on the side of the carrier 210). In some implementations, the conductive pillars 214 may extend from the carrier 210 to the VCSEL chip 202 (e.g., the solder caps 216 may be on the side of the VCSEL chip 202). A size, a shape, and a spacing of the conductive pillars 214 may correspond to a size, a shape, and a spacing of the clusters 208. In this way, the conductive pillars 214 may have a greater width or diameter (e.g., than the conductive pillars 214 would otherwise have if connected to individual VCSELs 204), thereby facilitating solder mass reflow (e.g., for bonding the VCSEL chip 202 and the carrier 210). In some implementations, TCB may be used for bonding the VCSEL chip 202 and the carrier 210.

In some implementations, multiple first VCSELs 204 may be grouped in a first cluster 208 and multiple second VCSELs 204 may be grouped in a second cluster 208. A first electrical contact 206 may be shared by the first VCSELs 204 and may be electrically connected to the first VCSELs 204. A second electrical contact 206 may be shared by the second VCSELs 204 and may be electrically connected to the second VCSELs 204. The second electrical contact may be electrically isolated from the first electrical contact.

As indicated above, FIG. 2 is provided as an example. Other examples may differ from what is described with regard to FIG. 2.

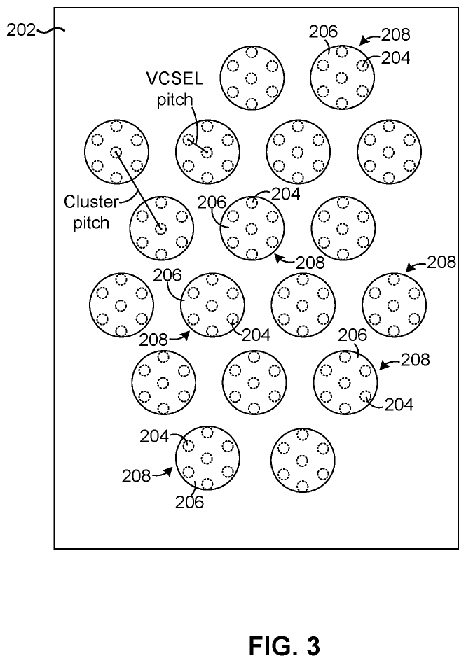

FIG. 3 shows a top view of an example of the VCSEL chip 202. As shown, the VCSELs 204 of the VCSEL chip 202 may be grouped into a plurality of clusters 208, and multiple VCSELs 204 of a cluster may be arranged non-linearly. For example, each of the plurality of clusters 208 may be circular in shape, and a respective electrical contact 206 may be associated with each cluster 208. Thus, a conductive pillar 214 (not shown in FIG. 3) for a cluster 208 may be cylindrical in shape. A spacing of the clusters 208 may define a pitch that is greater (e.g., at least two times greater, at least three times greater, at least four times greater, or at least five times greater) than the first pitch associated with the VCSELs 204, thereby facilitating the use of solder mass reflow.

As indicated above, FIG. 3 is provided as an example. Other examples may differ from what is described with regard to FIG. 3.

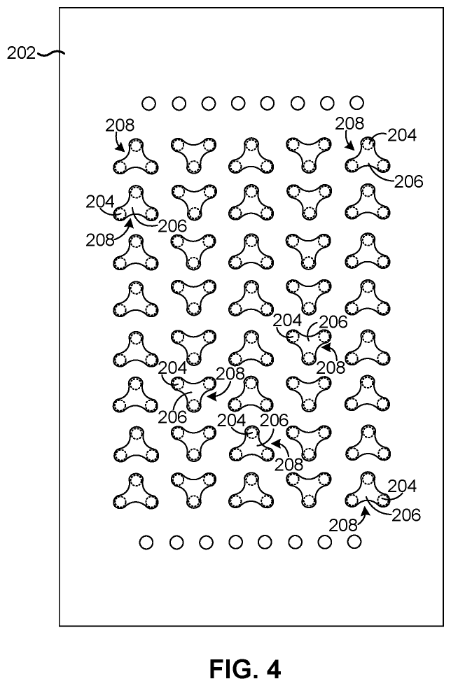

FIG. 4 shows a top view of an alternative configuration of an example of the VCSEL chip 202. As shown, the VCSELs 204 of the VCSEL chip 202 may be arranged, evenly-spaced, in a plurality of rows, and alternating rows may be shifted relative to each other. The VCSELs 204 may be grouped into a plurality of clusters 208, and multiple VCSELs 204 of a cluster may be arranged non-linearly. For example, each of the plurality of clusters 208 may be triangular in shape, and a respective electrical contact 206 may be associated with each cluster 208. Thus, a conductive pillar 214 (not shown in FIG. 4) for a cluster 208 may be triangular in shape (e.g., a cross-section of the conductive pillar 214 may be triangular in shape).

As indicated above, FIG. 4 is provided as an example. Other examples may differ from what is described with regard to FIG. 4.

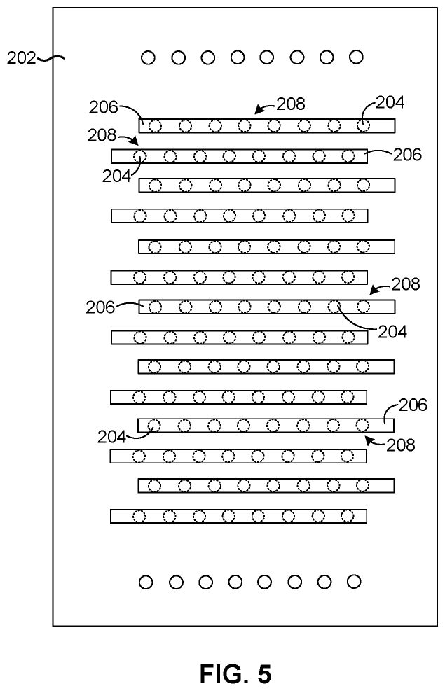

FIG. 5 shows a top view of an alternative configuration of an example of the VCSEL chip 202. As shown, the VCSELs 204 of the VCSEL chip 202 may be arranged, evenly-spaced, in a plurality of rows, and alternating rows may be shifted relative to each other. The VCSELs 204 may be grouped into a plurality of clusters 208 that are linear in shape (e.g., each row of VCSELs 204 may be grouped into a respective cluster 208), and a respective electrical contact 206 may be associated with each cluster 208. Thus, a conductive pillar 214 (not shown in FIG. 5) for a cluster 208 may be bar (e.g., rectangular) shaped.

As indicated above, FIG. 5 is provided as an example. Other examples may differ from what is described with regard to FIG. 5.

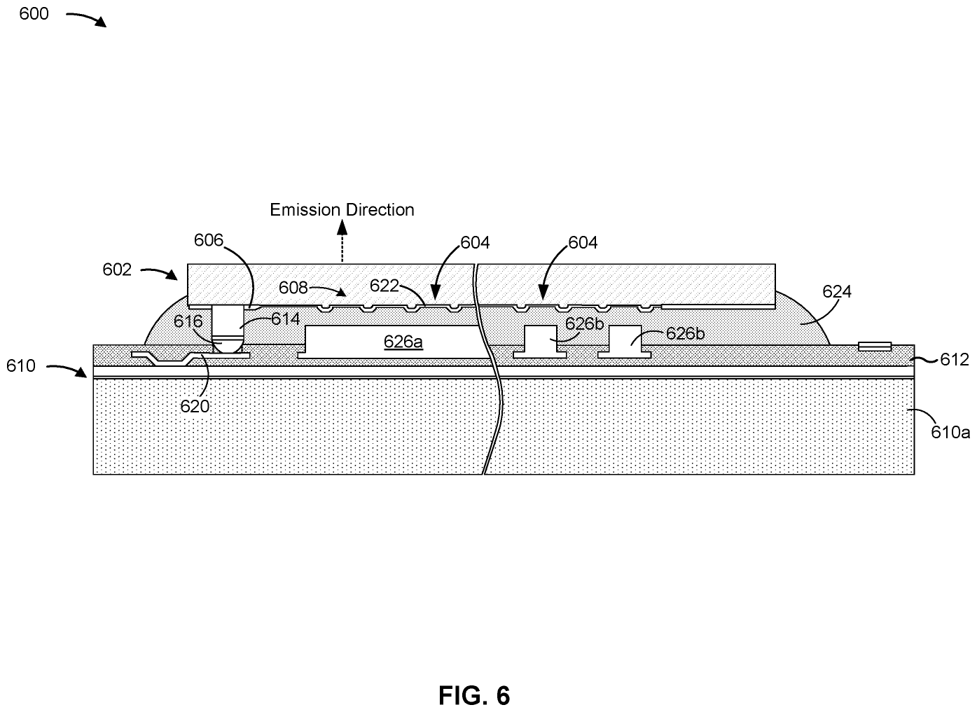

FIG. 6 shows a sectional view of an example emitter assembly 600. The emitter assembly 600 may include a VCSEL chip 602 (e.g., a VCSEL device) that includes a plurality of VCSELs 604 and a plurality of first electrical contacts 606 (e.g., bond pads), in a similar manner as described in connection with FIG. 2. For example, the VCSELs 604 may be arranged in accordance with a fine pitch. The emitter assembly 600 may include a carrier 610 for the VCSEL chip 602 that includes a plurality of second electrical contacts (not shown), in a similar manner as described in connection with FIG. 2. In addition, the carrier 610 may include a base layer 610a and a surface layer 612 disposed on the base layer 610a, in a similar manner as described in connection with FIG. 2. For example, the emitter assembly 600 may include a VOD device. As one example, the surface layer 612 may include a redistribution layer that includes a plurality of conductive traces 620, in a similar manner as described in connection with FIG. 2.

Multiple VCSELs 604 may be grouped in a cluster 608, and the cluster 608 of VCSELs 604 may share an electrical contact 606 (i.e., a common electrical contact 606), in a similar manner as described in connection with FIG. 2. For example, the multiple VCSELs 604 of the cluster 608 may be arranged in a row. In some implementations, the electrical contact 606 for the cluster 608 may be located outside of a region occupied by the multiple VCSELs 604 grouped in the cluster 608. For example, as shown, the electrical contact 606 may be located at an end of the row of the multiple VCSELs 604 grouped in the cluster 608. Thus, the multiple VCSELs 604 of the row may be electrically connected to each other and electrically led out to the electrical contact 606 by a conductive layer 622 (e.g., a copper layer) disposed on the VCSELs 604. In some implementations, an area of an electrical contact 606 may be greater than an area of a VCSEL 604.

In some implementations, the emitter assembly 600 may include a plurality of conductive pillars 614 (e.g., posts, columns, or the like), with respective solder caps 616, that connect the VCSEL chip 602 and the carrier 610, in a similar manner as described in connection with FIG. 2. A conductive pillar 614 may electrically connect the electrical contact 606 for the multiple VCSELs 604 grouped in the cluster 608 and an electrical contact of the carrier 610. For example, a first end of the conductive pillar 614 may be electrically and mechanically connected to the electrical contact 606, and a second end of the conductive pillar 614 may be electrically and mechanically connected to the electrical contact of the carrier (e.g., via a conductive trace 620 of the surface layer 612). In some implementations, the conductive pillar 614 may extend from the VCSEL chip 602 to the carrier 610 (e.g., the solder cap 616 may be on the side of the carrier 610). In some implementations, the conductive pillar 614 may extend from the carrier 610 to the VCSEL chip 602 (e.g., the solder cap 616 may be on the side of the VCSEL chip 602). Because an area of the electrical contact 606 may be greater than an area of a VCSEL 604, the conductive pillar 614 may have a greater width or diameter, thereby facilitating solder mass reflow (e.g., for bonding the VCSEL chip 602 and the carrier 610). In some implementations, TCB may be used for bonding the VCSEL chip 602 and the carrier 610.

The emitter assembly 600 may include underfill 624 between the VCSEL chip 602 and the carrier 610. The underfill 624 may provide structural support for the VCSEL chip 602 (e.g., for a middle portion of the VCSEL chip 602 where there are no conductive pillars 614 to provide support). In some implementations, the emitter assembly 600 may include one or more thermal elements 626 (shown as a thermal element 626a and thermal elements 626b). The thermal element(s) 626 may be composed of a thermally-conductive material, such as a metal (e.g., copper). The thermal element(s) 626 may be on the carrier 610 (e.g., plated on the carrier 610). For example, the thermal element(s) 626 may be disposed on the surface layer 612 or partially embedded in the surface layer 612. The thermal element(s) 626 may extend toward the VCSEL chip 602 without contacting the VCSEL chip 602 (e.g., a region of the underfill 624 may separate the VCSEL chip 602 from the thermal element(s) 626).

In some implementations, the thermal element 626a may include a bar aligned with multiple VCSELs 604 grouped in a cluster 608. For example, the bar may extend along a row of VCSELs 604. As another example, a footprint of the bar may encompass the entire array of VCSELs 604. In some implementations, a thermal element 626b may include a pillar aligned with a single VCSEL 604. The thermal element(s) 626 may transfer heat generated by the VCSEL chip 602 to the carrier 610, thereby providing compensation for the thermal resistance of the underfill 624.

As indicated above, FIG. 6 is provided as an example. Other examples may differ from what is described with regard to FIG. 6.

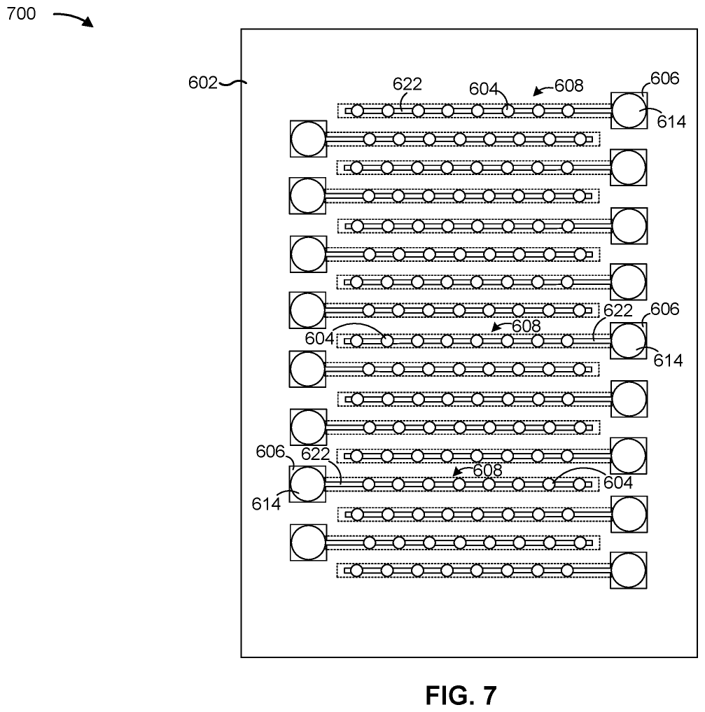

FIG. 7 shows a top view of an example of the VCSEL chip 602. As shown, the VCSELs 604 of the VCSEL chip 602 may be arranged in a plurality of rows and each row of VCSELs 604 may be grouped into a cluster 608. As described herein, the VCSELs 604 of the cluster 608 may be electrically connected to each other, and to an electrical contact 606, by a conductive layer 622. As shown, a respective electrical contact 606 may be located at an end of each row of VCSELs 604 (e.g., each cluster 608). As further shown, alternating rows of VCSELs 604 may be associated with electrical contacts 606 at opposite ends of the rows, thereby facilitating maximization of areas of the electrical contacts 606. The dashed lines in FIG. 7 show locations on the carrier 610 of respective thermal elements 626 for each row of VCSELs 604. Respective conductive pillars 614 may be electrically connected to the electrical contacts 606. Thus, control of the VCSELs 604 (e.g., turning on or turning off of the VCSELs 604) may be per cluster 608 (e.g., per row). Because areas of the electrical contacts 606 may be greater than an area of a VCSEL 604, the conductive pillars 614 may have a greater width or diameter, thereby facilitating solder mass reflow.

As indicated above, FIG. 7 is provided as an example. Other examples may differ from what is described with regard to FIG. 7.

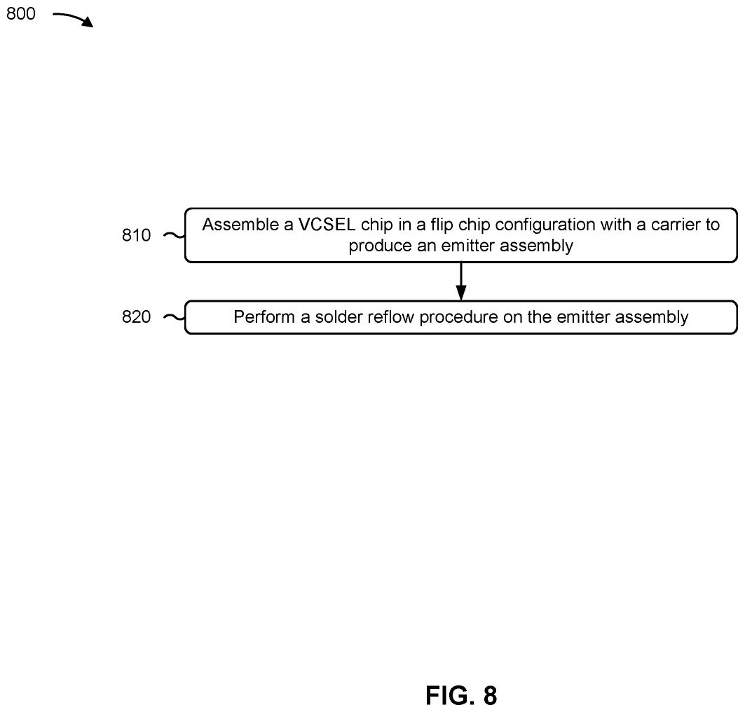

FIG. 8 is a flowchart of an example process 800 associated with manufacturing an emitter assembly with VCSEL clusters. In some implementations, one or more process blocks of FIG. 6 may be performed by various semiconductor manufacturing equipment, various circuit board assembly equipment, and/or various solder reflow equipment (e.g., which may include one or more conveyors and/or one or more reflow ovens).

As shown in FIG. 8, process 800 may include assembling a VCSEL chip in a flip chip configuration with a carrier to produce an emitter assembly (block 810). In some implementations, the VCSEL chip includes a plurality of VCSELs, and multiple VCSELs, of the plurality of VCSELs, are grouped in a cluster that shares an electrical contact. In some implementations, a conductive pillar is to electrically connect to the electrical contact of the cluster of the multiple VCSELs. In some implementations, process 800 includes applying solder flux on the carrier prior to assembling the VCSEL chip in the flip chip configuration with the carrier.

As further shown in FIG. 8, process 800 may include performing a solder reflow procedure on the emitter assembly (block 820). In some implementations, the VCSEL chip and the carrier are passively aligned in the solder reflow procedure. In some implementations, the solder reflow procedure causes electrical connection of the conductive pillar and the electrical contact. In some implementations, process 800 may include forming the VCSEL chip, forming the carrier, and/or forming an assembly that includes the emitter assembly.

Although FIG. 8 shows example blocks of process 800, in some implementations, process 800 includes additional blocks, fewer blocks, different blocks, or differently arranged blocks than those depicted in FIG. 8. Additionally, or alternatively, two or more of the blocks of process 800 may be performed in parallel.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” “top,” “bottom,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. An emitter assembly, comprising:
a vertical cavity surface emitting laser (VCSEL) chip comprising a plurality of VCSELs in a bottom-emitting configuration,
wherein multiple VCSELs, of the plurality of VCSELs, are grouped in a cluster; a carrier,
wherein the VCSEL chip is in a flip chip configuration with the carrier; and
a conductive pillar electrically connected to the multiple VCSELs grouped in the cluster.

2. The emitter assembly of claim 1, wherein the carrier comprises an integrated circuit chip or a substrate.

3. The emitter assembly of claim 1, wherein the carrier comprises a surface layer and a base layer, and
wherein the surface layer comprises a redistribution layer.

4. The emitter assembly of claim 1, wherein the conductive pillar has a solder cap at an end of the conductive pillar, and
wherein the solder cap surrounds the multiple VCSELs.

5. The emitter assembly of claim 1, wherein the conductive pillar has a solder cap at an end of the conductive pillar, and
wherein the solder cap is electrically connected to the multiple VCSELs.

6. The emitter assembly of claim 1, wherein the conductive pillar electrically connects the cluster of the multiple VCSELs and the carrier.

7. The emitter assembly of claim 1, wherein the conductive pillar extends from the VCSEL chip to the carrier.

8. The emitter assembly of claim 1, wherein the conductive pillar extends from the carrier to the VCSEL chip.

9. The emitter assembly of claim 1, further comprising:
underfill between the VCSEL chip and the carrier.

10. The emitter assembly of claim 9, wherein the carrier comprises:
a thermal element aligned with the multiple VCSELs grouped in the cluster,
wherein the thermal element is separated from the VCSEL chip by the underfill.

11. A vertical cavity surface emitting laser (VCSEL) chip, comprising:
a plurality of VCSELs in a bottom-emitting configuration,
wherein multiple VCSELs, of the plurality of VCSELs, are grouped in a cluster; and
an electrical contact shared by the multiple VCSELs grouped in the cluster,
wherein the electrical contact is electrically connected to the multiple VCSELs, and
wherein the electrical contact is configured to electrically connect to a conductive pillar that provides electrical connection of the VCSEL chip and a carrier.

12. The VCSEL chip of claim 11, wherein the multiple VCSELs grouped in the cluster are arranged in a row.

13. The VCSEL chip of claim 11, wherein the multiple VCSELs grouped in the cluster are arranged non-linearly.

14. The VCSEL chip of claim 11, wherein the electrical contact is outside of a region occupied by the multiple VCSELs grouped in the cluster.

15. The VCSEL chip of claim 11, wherein the multiple VCSELs are multiple first VCSELs, the cluster is a first cluster, and the electrical contact is a first electrical contact,
wherein multiple second VCSELs, of the plurality of VCSELs, are grouped in a second cluster, and
wherein the VCSEL chip further comprises:
a second electrical contact, electrically isolated from the first electrical contact, shared by the multiple second VCSELs,
wherein the second electrical contact is electrically connected to the multiple second VCSELs.

16. The VCSEL chip of claim 11, wherein a spacing of the plurality of VCSELs defines a pitch that is less than 45 micrometers.

17. A method, comprising:
assembling a vertical cavity surface emitting laser (VCSEL) chip in a flip chip configuration with a carrier to produce an emitter assembly,
wherein the VCSEL chip comprises a plurality of VCSELs, and multiple VCSELs, of the plurality of VCSELs, are grouped in a cluster that shares an electrical contact, and
wherein a conductive pillar is to electrically connect to the electrical contact of the cluster of the multiple VCSELs; and
performing a solder reflow procedure on the emitter assembly.

18. The method of claim 17, wherein the VCSEL chip and the carrier are passively aligned in the solder reflow procedure.

19. The method of claim 17, wherein the solder reflow procedure causes electrical connection of the conductive pillar and the electrical contact.

20. The method of claim 17, further comprising:
applying solder flux on the carrier prior to assembling the VCSEL chip in the flip chip configuration with the carrier.
